(19) United States
(12) Patent Application Publication
(10) Pub. No.: US 2018/0364492 A1
(43) Pub. Date: Dec. 20, 2018

(54) BEAM SPLITTER FOR ACHIEVING GRAZING INCIDENCE OF LIGHT

(71) Applicant: Carl Zeiss SMT GmbH, Oberkochen (DE)

(72) Inventor: Konstantin Forcht, Aalen (DE)

(21) Appl. No.: 16/113,585

(22) Filed: Aug. 27, 2018

Related U.S. Application Data
(63) Continuation of application No. PCT/EP2017/053598, filed on Feb. 17, 2017.

(30) Foreign Application Priority Data
Mar. 8, 2016 (DE) 10 2016 203 749.8

(51) Int. Cl. G02B 27/12; G02B 21/00; G02B 21/16; G03F 7/20

(52) U.S. Cl. CPC G02B 27/12; G02B 21/0016; G03F 7/7065; G02B 27/126; G02B 21/16

(57) ABSTRACT

The disclosure relates to an optical system, in particular for microscopy, which includes a beam splitter having a light entrance surface and a light exit surface, wherein the beam splitter absorbs. For a specified operating wavelength range of the optical system, less than 20% of electromagnetic radiation is incident on the light entrance surface. The beam splitter is arranged in the optical system such that the angles of incidence which occur during operation of the optical system at the light entrance surface and/or at the light exit surface, with reference to the respective surface normal, are at least 70°.

### CROSS-REFERENCE TO RELATED APPLICATIONS

The present application is a continuation of, and claims benefit under 35 USC 120 to, international application PCT/EP2017/053598, filed Feb. 17, 2017, which claims benefit under 35 USC 119 of German Application No. 10 2016 203 749.8, filed Mar. 8, 2016. The entire disclosure of these applications are incorporated by reference herein.

### FIELD

The disclosure relates to an optical system, in particular for microscopy. The disclosure is able to be advantageously used in a wide variety of application fields, for example in microscopy applications in the material sciences field, in biology or various other basic research. A further possible use of the disclosure is a mask inspection system for inspecting reticles or masks for use in a microlithographic projection exposure apparatus.

### BACKGROUND

In brightfield reflected-light microscopy, the object to be investigated is illuminated using a beam splitter, which is tilted relative to the illumination light that is incident from a light source and which deflects the light onto the object to be investigated. To increase the attainable resolution, a transition to increasingly lower operating wavelengths is desirable in this case.

In optical systems designed for the EUV range, i.e. at wavelengths of less than 30 nm (e.g. approximately 13 nm or approximately 7 nm), owing to the lack of availability of suitable light-transmissive refractive materials, mirrors are used as optical components for the imaging process. This is also true for systems which are designed for shortwave VUV radiation (e.g. wavelengths below 150 nm), because such systems are also preferably designed as mirror systems.

In the above-mentioned applications, beam splitters are used which transmit and reflect proportions of the respective illumination light in order to, on the one hand, direct the relevant electromagnetic radiation onto a sample to be investigated (e.g. arranged in the object plane of a microscope objective) and, on the other hand, to supply it to a detector. The desired properties that exist here in practice also generally include—in addition to a minimization of occurring absorption and scattering losses—that the proportions which are separated at the beam splitter (i.e. the transmitted proportion and the reflected proportion of the electromagnetic radiation) are, if possible, identical in terms of intensity (what is known as a “50/50 beam splitter”).

To minimize absorption losses in the respective operating wavelength, in particular the implementation of beam splitters with dielectric layer systems is known, which have a sequence of individual layers made of materials having a different refractive index.

However, in practice frequently the issue can arise that, to cover a larger wavelength range, in principle a large multiplicity of different dielectric layers is desired, which in turn involves increasing absorption losses due to the multiplicity of interfaces with increasing stray light proportions and in particular at low wavelengths of e.g. less than 150 nm.

### SUMMARY

The present disclosure seeks to provide an optical system, in particular for microscopy, wherein beam splitting over a comparatively large wavelength range is made possible while avoiding the previously described problems.

In accordance with one aspect of the disclosure, an optical system, in particular for microscopy, includes: a beam splitter having a light entrance surface and a light exit surface; wherein the beam splitter absorbs, for a specified operating wavelength range of the optical system, less than 20% of electromagnetic radiation that is incident on the light entrance surface; and wherein the beam splitter is arranged in the optical system such that the angles of incidence which occur during operation of the optical system at the light entrance surface and/or at the light exit surface, with reference to the respective surface normal, are at least 70°.

The disclosure involves the concept of a passage through at least one interface of a beam splitter, located in the optical beam path, with relatively high angles of incidence (with reference to the respective surface normal) in an optical system, such as a microscope, with the consequence that even without using a coating, such as a dielectric layer system, at the beam splitter a relatively high reflectivity is realized and, as a result, a high throughput is able to be attained (which may be comparable to beam splitters in the visible spectral range and close to the theoretical ideal value of 25%).

Due to the omission of the (e.g. dielectric) coating or structuring of the beam splitter according to the disclosure, the problems of layer degradation which typically occur in such layer systems can be avoided, as a result of which the production effort and costs can be significantly reduced. Furthermore, due to the omission of a layer system which is formed from a multiplicity of dielectric individual layers, absorption and scatter losses can be minimized.

Due to the functional principle of the beam splitter according to the disclosure, a beam split with high broadbandedness with respect to the possible operating wavelength range is already “intrinsically” attained, wherein, depending on the embodiment, operating wavelengths of below 120 nm (in particular also in the EUV range, i.e. less than 30 nm, in particular less than 15 nm) and into the infrared spectral range are realizable.

According to an embodiment, the beam splitter is arranged in the optical system in such a way that the angles of incidence occurring at the light entrance surface and/or at the light exit surface during operation of the optical system, with reference to the respective surface normal, are at least 75°, in particular at least 80°.

In accordance with one embodiment, the beam splitter has a plane-parallel geometry. It can have in this case in particular a thickness of less than 1 mm, more particularly less than 0.5 mm. As a result, a comparatively low or minimum optical path within the respective material of the beam splitter can be realized, with the consequence that absorption losses, an unavoidable beam offset between the light proportions which are reflected at the two interfaces of the beam splitter, and also chromatic aberrations can be minimized.

In accordance with a further embodiment, the beam splitter has at least one component with wedge-shaped or wedge-section-shaped geometry. An implementation of this type has in particular the advantage that, after multiple reflections within the beam splitter, light proportions that exit with a beam offset can be relatively easily blocked out due to the exit angles that differ from the exiting “used light,” and thus a disturbing influence of such light proportions on the imaging result can be avoided.

In accordance with a further embodiment, the beam splitter has a prism-shaped geometry. Such an implementation has in particular the advantage that, with integration of the beam splitter in the optical (overall) system, a generally desired realization of 90° deflections between incident and transmitted beam is possible without additional folding or deflection mirror and thus with a reduction of the total number of optical components or mirrors.

According to one embodiment, the beam splitter is made from a material selected from the group including magnesium fluoride (MgF₂), lithium fluoride (LiF), aluminum fluoride (AlF₃), calcium fluoride (CaF₂) and barium fluoride (BaF₂).

In accordance with one embodiment, the beam splitter consists only of this material.

In accordance with one embodiment, the beam splitter has at least one uncoated component having the light entrance surface and/or the light exit surface. In other words, the beam splitter preferably has no (e.g. dielectric) coating whatsoever, with the result that in particular no layer degradation can occur either.

According to an embodiment, the optical system is designed for an operating wavelength of less than 150 nm, in particular less than 120 nm.

According to an embodiment, the optical system is designed for an operating wavelength of less than 30 nm, more particularly less than 15 nm.

According to an embodiment, the optical system is a microscope.

According to one embodiment, the optical system is a mask inspection system for inspecting reticles or masks for use in a microlithographic projection exposure apparatus.

Further configurations of the disclosure can be gathered from the description and the claims.

### BRIEF DESCRIPTION OF THE DRAWINGS

The disclosure is explained in greater detail below on the basis of exemplary embodiments illustrated in the accompanying figures, in which:

FIGS. 1-9 show schematic illustrations for elucidating various exemplary embodiments of a beam splitter that is used in an optical system according to the disclosure;

FIGS. 10 and 11 show diagrams for illustrating the possible profile of the wavelength dependence of the throughput that is attainable with a beam splitter according to the disclosure (FIG. 10) and of the reflection coefficient and the transmission coefficient for s-polarized and p-polarized light (FIG. 11); and

FIG. 12 shows a schematic illustration for elucidating the design of a conventional brightfield reflected-light microscope.

### DETAILED DESCRIPTION OF PREFERRED EMBODIMENTS

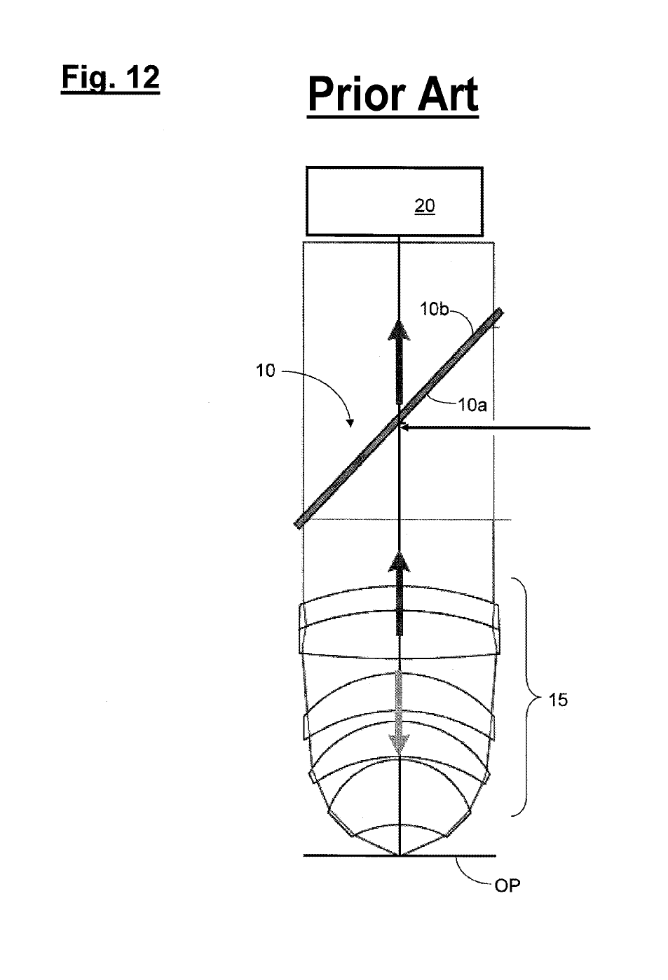

FIG. 12 shows a merely schematic illustration for elucidating the design of a conventional brightfield reflected-light microscope.

In the design of a brightfield reflected-light microscope shown schematically in FIG. 12, illumination light is incident on a beam splitter 10, where a proportion is reflected and a proportion is transmitted at the first interface 10a thereof. The reflected proportion passes through a microscope objective 15 to the object plane OP, where it is reflected at a sample to be investigated that is located in the object plane OP, and passes, again after proportional transmission, through the beam splitter 10 via the second interface 10b thereof to a detector 20.

The disclosure is not limited to the realization in such a microscope. For example, the disclosure, or the beam splitter having a design in accordance with the disclosure, can in further applications also be realized e.g. in a mask inspection system for inspecting reticles or masks for use in a projection exposure apparatus of a mask inspection apparatus or in another optical system.

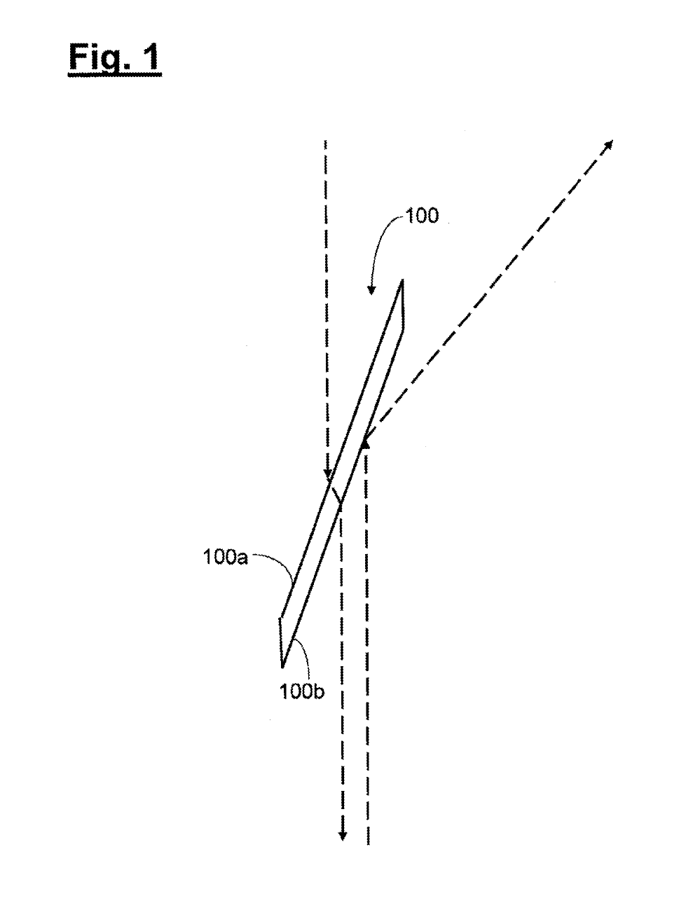

Various embodiments of a beam splitter according to the disclosure will be described below with reference to the schematic illustrations of FIGS. 1 to 9.

FIG. 1 shows, in a merely schematic illustration, a beam splitter 100, which is embodied as a plane plate with mutually parallel interfaces 100a, 100b. The beam splitter 100 is arranged in the optical beam path in a manner such that the angle of incidence of the electromagnetic radiation that is incident on the light entrance surface which is formed by the first interface 100a is at least 70° (wherein here and below, the angle of incidence in each case is with reference to the surface normal).

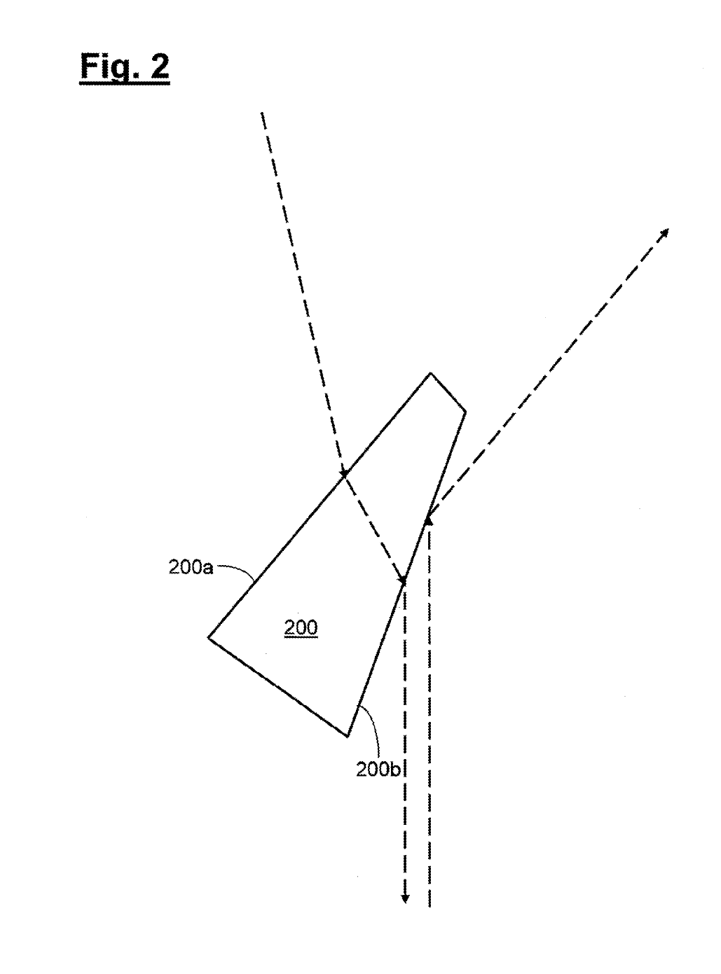

In FIG. 1, just as in the further FIGS. 2-8, the illumination light which is coming from the light source (not illustrated) is incident on the beam splitter in each case in the illustration from above, wherein in these illustrations, the sample to be inspected (on which the light that is transmitted by the beam splitter 100 is incident) and the detector (to which the light that is returned by the sample to be investigated and is then reflected at the second interface 100b finally passes) are not illustrated in each case.

To minimize absorption losses, the beam splitter 100 preferably has a thickness of less than 1 mm, in particular less than 0.5 mm. Furthermore, the beam splitter 100 is produced from a material which is sufficiently transmissive or light-transmissive in the respective operating wavelength range. The material and thickness of the beam splitter is preferably selected such that the beam splitter absorbs, for a specified operating wavelength range of the optical system, less than 20% of electromagnetic radiation that is incident on the light entrance surface. At operating wavelengths in the region around 120 nm or below, e.g. magnesium fluoride (MgF₂) is a suitable material.

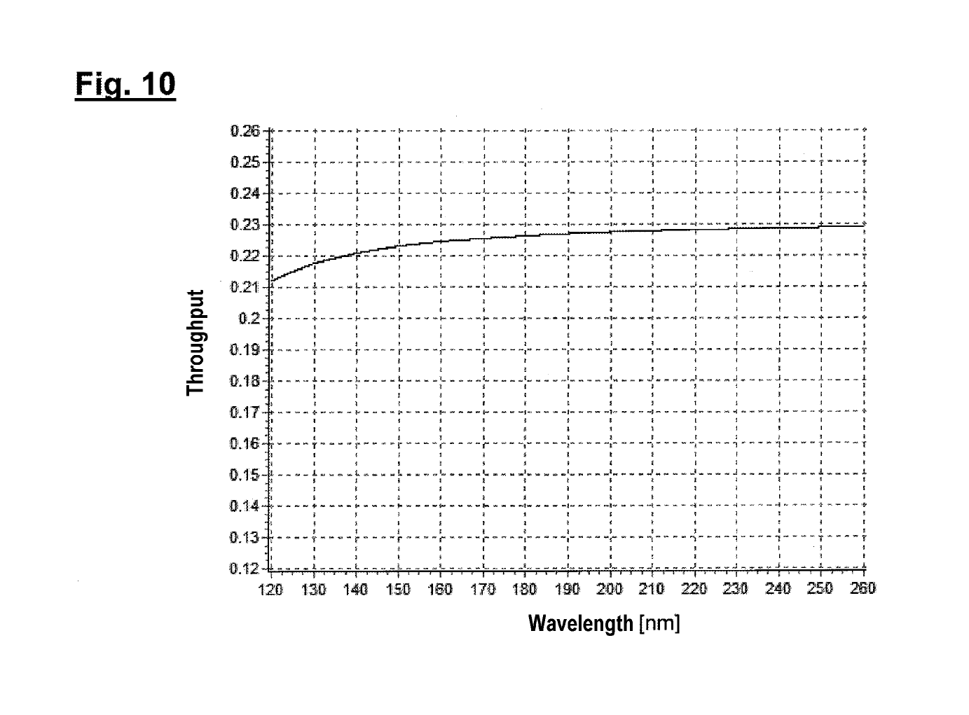

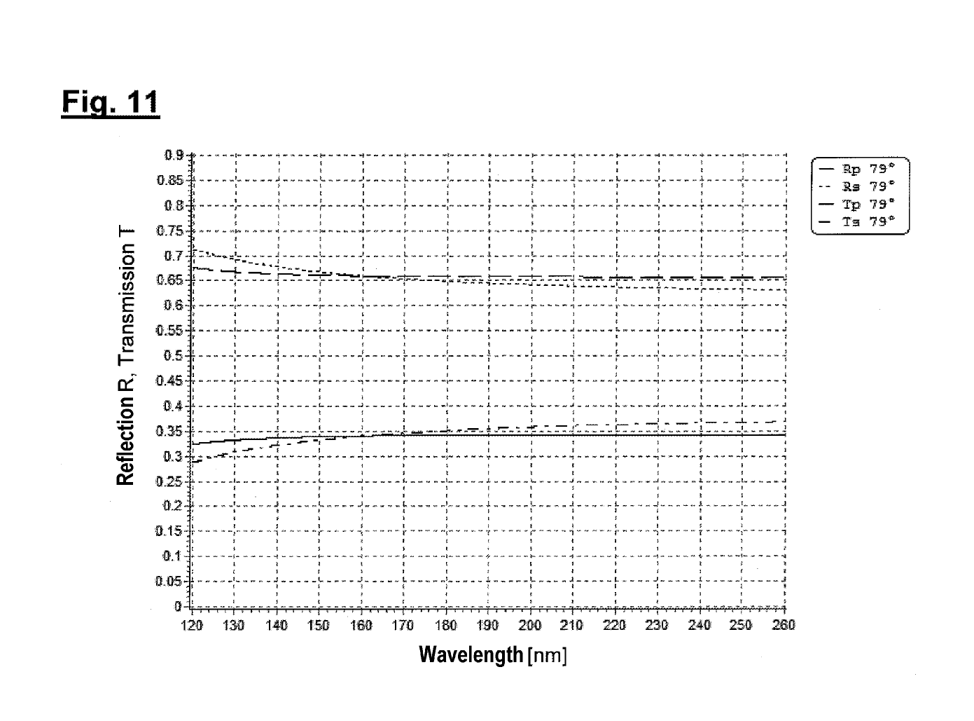

FIG. 10 and FIG. 11 show diagrams for elucidating the possible profile of the wavelength dependence of the throughput that is attainable with a beam splitter according to the disclosure, wherein the beam splitter is designed as a plane plate made of magnesium fluoride (MgF₂), with the angle of incidence, which is with reference to the surface normal, on the light entrance surface of said plane plate in the optical system being 79°. According to FIG. 10, the average attainable throughput D is approximately at 22°, wherein the throughput D is given by D=(Rₛ*Tₛ+Rₚ*Tₚ)/2. This value is comparable to values which are attainable with beam splitters in the visible spectral range and is close to the theoretical ideal value of 25%.

FIG. 11 shows the respective profile of the reflection coefficient and of the transmission coefficient both for the proportion with s-polarization and for the proportion with p-polarization. The average values of the reflection proportion and the transmission proportion over both polarization directions are for both polarization proportions in each case approximately the desired value of 50%, wherein the polarization ratio (Rₚ+Tₚ)/(Rₛ+Tₛ) is close to the desired value of one.

In further embodiments, the beam splitter 100 can also be produced with an even lower thickness (e.g. including as a thin film made of silicon (Si)). Advantageous is a thickness, which is as low as possible due to the absorption losses, of less than 1 μm, with further preference a thickness of less than 100 nm.

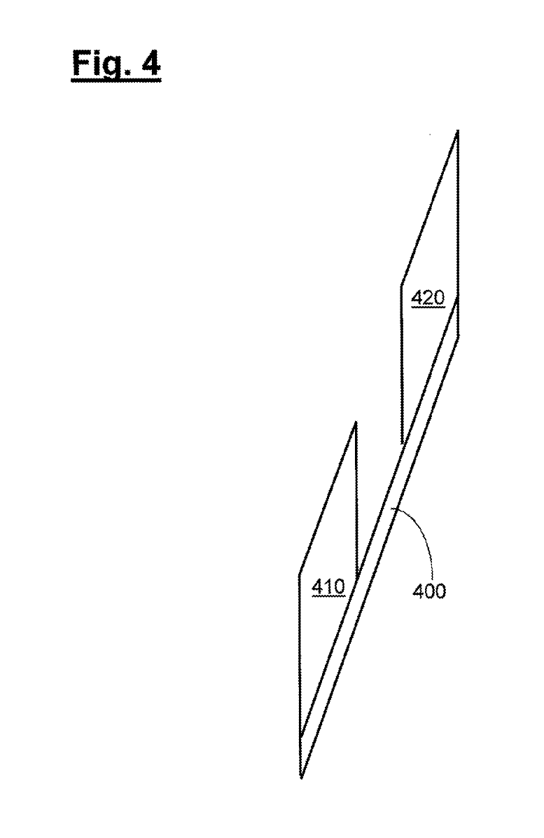

One embodiment for ensuring sufficient stability or avoidance of undesired impairment of the imaging quality due to any surface deformations of the beam splitter is illustrated merely schematically in FIG. 4. According to FIG. 4, an improvement of the mechanical stability of a beam splitter 400 can be attained by way of (e.g. contact-bonded) support elements e.g. in the form of ring segments or frame segments, which can in particular consist of the same material as the beam splitter 400 itself. In FIG. 4, such support elements are indicated merely schematically and denoted with “410” and “420.” With respect to the concrete implementation of such support elements, the disclosure is not limited, wherein for example a central support by way of struts or the like may also be provided.

Once again with reference to FIG. 1, the drawn beam path is strongly simplified in as far as unavoidable multiple reflections occur within the beam splitter 100, wherein the corresponding proportions, which have been reflected multiple times, have, after exit from the beam splitter 100, a beam offset.

In order to simplify elimination of such light proportions which have a disturbing effect for highly precise imaging, the beam splitter according to the disclosure can also have, as shown in FIG. 2, a wedge-shaped or wedge-section-shaped geometry. Hereby, output coupling of the above-described, undesired light proportions is made easier due to the exit angles that differ from the used light.

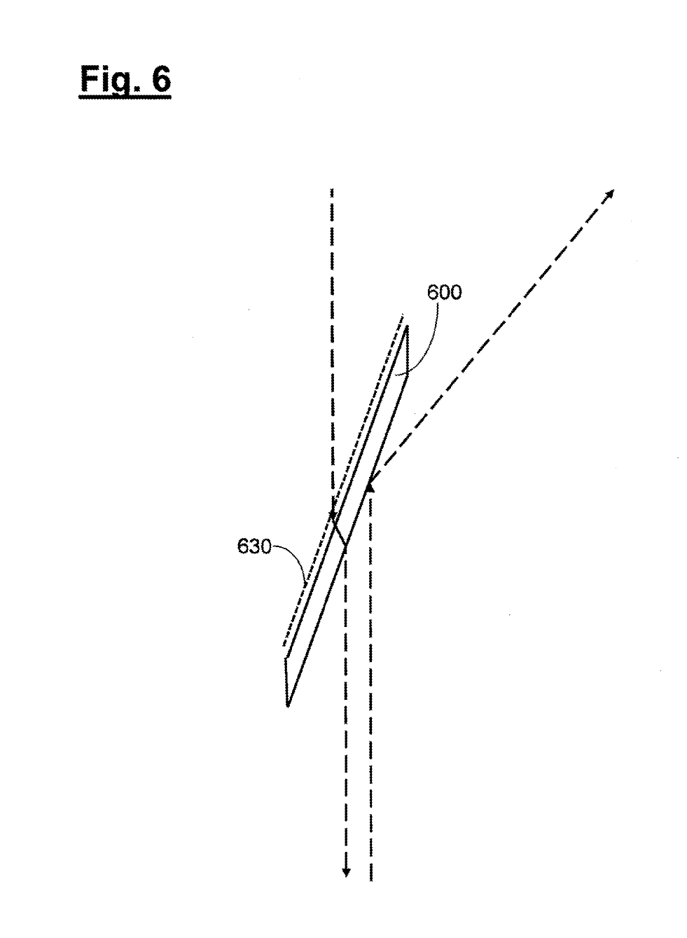

Since in the implementation of the beam splitter 200 described above with wedge-shaped or wedge-section-shaped geometry one of the interfaces (specifically the first interface 200a) does not contribute to the reflection proportion, the transmission proportion at this interface is preferably as great as possible. To this end, the angle of incidence at the relevant interface is preferably significantly smaller than at the other (reflective) interface, wherein the angle of incidence at the relevant interface which does not contribute to the reflection proportion preferably can be selected to be smaller than 65°. In further embodiments, it is possible, as indicated in FIG. 6, for a reflection-reducing coating 630 (indicated by a dashed line in FIG. 6) to be applied on the interface of a beam splitter 600 which does not contribute to the reflection proportion.

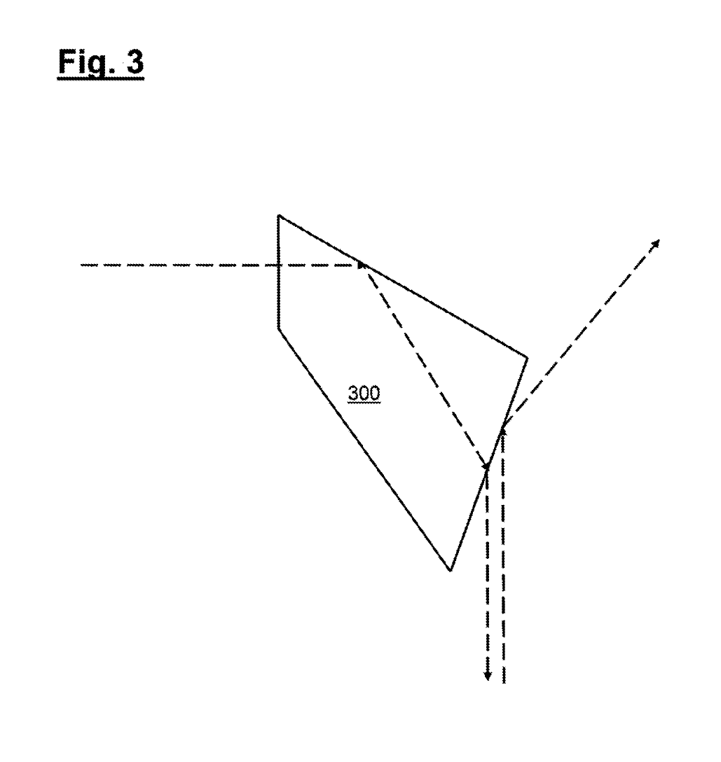

FIG. 3 shows a further embodiment of a beam splitter 300 according to the disclosure, which has a prism-shaped geometry. Such an implication first can have the effect of a more significant separation between transmitted and reflected light proportions with the setting of greater angles between said light proportions. Furthermore, with a suitable implementation of the relevant prism, it is already possible to realize a beam deflection which is possibly desired in the overall system due to the total internal reflection occurring within the beam splitter 300, e.g. in order to attain a mutually orthogonal orientation of illumination light on the one hand, and imaging light that is incident on the object plane on the other hand, without further deflection or folding mirrors.

In the previously described implementation of the beam splitter according to the disclosure as a prism, the above statements relating to the highest possible transmission proportion of the interface which does not contribute to the reflection proportion or the preferably performed selection of correspondingly lower angles of incidence at the relevant interface analogously apply.

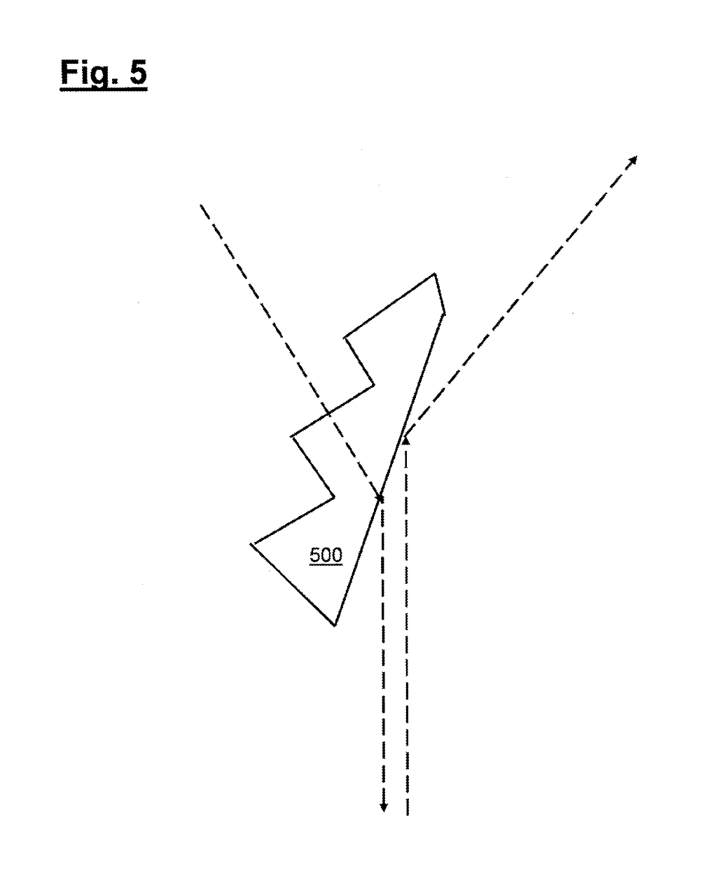

FIG. 5 shows a further embodiment of a beam splitter 500 according to the disclosure, which has a plurality of wedge-segment-shaped sections. The optical path within the beam splitter 500 and associated absorption losses can be minimized hereby, wherein the angle of incidence at the interface which does not contribute to the reflection can furthermore also be minimized.

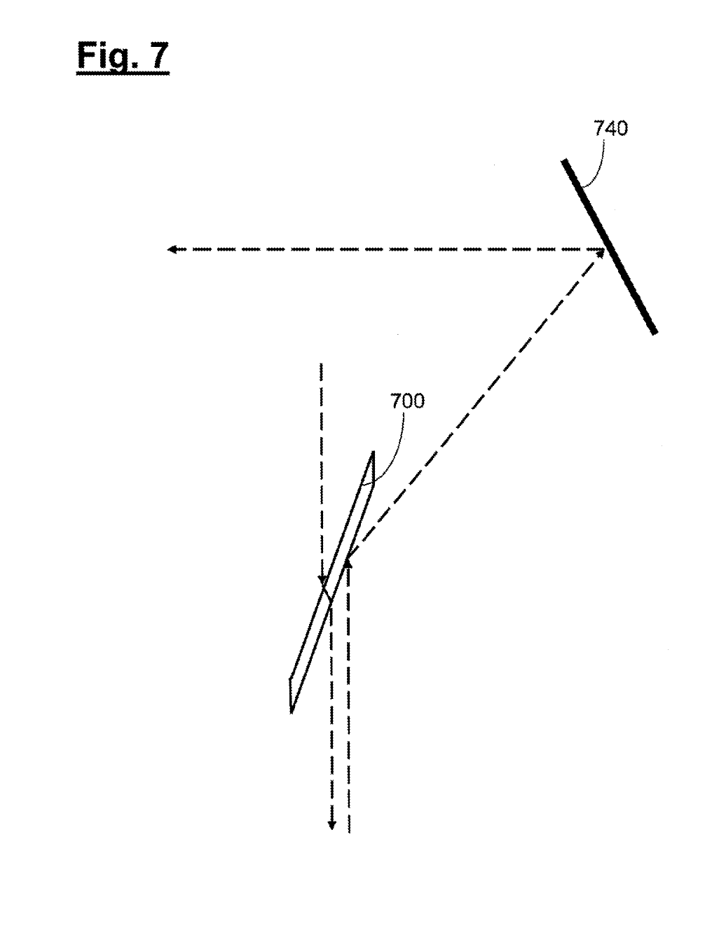

According to FIG. 7, an additional mirror 740 can also be provided to deflect the light, which is reflected at the second interface of a beam splitter 700, which has been designed analogously with respect to FIG. 1, in a direction that is parallel to the placement surface of the overall system.

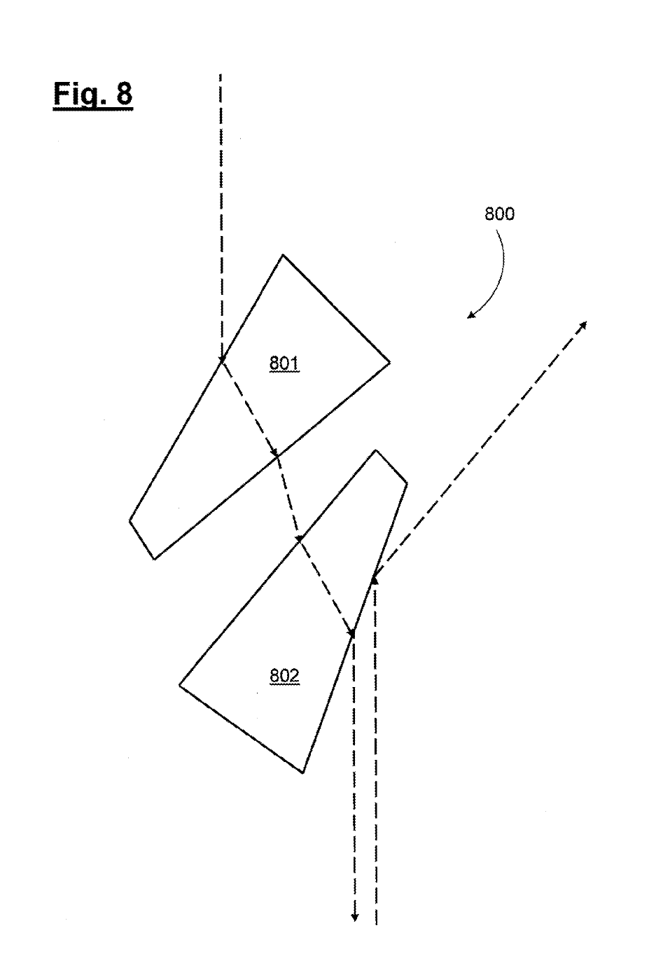

FIG. 8 shows a further embodiment of a beam splitter 800 according to the disclosure, which has two wedge-section-shaped subelements 801 and 802. In this way, a correction of a wavelength-dependent change in the deflection angle of the beam that is transmitted by the first subelement 801 can be attained by arranging the second subelement with an orientation that is rotated about 180° relative to the first subelement 801.

Furthermore, due to the use of a second subelement in the beam splitter according to the disclosure or owing to an asphere which is formed on an interface of the beam splitter, an astigmatic wavefront error can also be corrected.

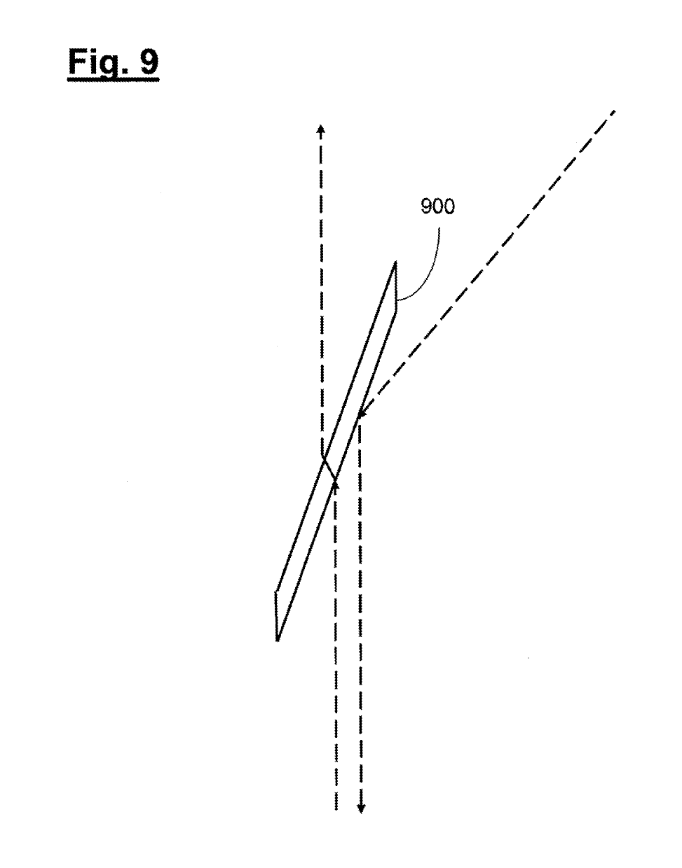

In further embodiments, the beam splitter according to the disclosure can also be arranged in the optical system such that the optical beam path is in each case reversed as compared to the previously described embodiments. FIG. 9 shows for illustration purposes an implementation, which is analogous with respect to FIG. 1, with a reversed beam path. This implementation can be advantageous in as far as the desired properties of the imaging quality in the illumination beam path are lower, with the result that any surface deformations present on the beam splitter 900 (e.g. due to an implementation of the beam splitter 900 in the form of a thin film), which results in wavefront errors in the reflected light proportion, have no influence on the imaging quality.

Even though the disclosure has been described on the basis of specific embodiments, numerous variations and alternative embodiments are apparent to a person skilled in the art, for example by combination and/or exchange of features of individual embodiments. Accordingly, it goes without saying for a person skilled in the art that such variations and alternative embodiments are concomitantly encompassed by the present disclosure, and the scope of the disclosure is restricted only within the meaning of the accompanying patent claims and the equivalents thereof.

What is claimed is:

1. An optical system, comprising:
a beam splitter having a light entrance surface and a light exit surface,
wherein:
the beam splitter is configured so that, during use of the optical system:
for an operating wavelength range of the optical system, the beam splitter absorbs less than 20% of electromagnetic radiation incident on the light entrance surface; and
at at least one surface selected from the group consisting of the light entrance surface and the light exit surface, angles of incidence of the electromagnetic radiation are at least 70° with respect to a normal to the surface; and
the optical system is selected from the group consisting of a microscope and a mask inspection system configured to inspect microlithography masks.

2. The optical system of claim 1, wherein the angles of incidence of the electromagnetic radiation are at least 75° with respect to the normal to the surface.

3. The optical system of claim 1, wherein the angles of incidence of the electromagnetic radiation are at least 80° with respect to the normal to the surface.

4. The optical system of claim 1, wherein the beam splitter has a maximum thickness of less than one millimeter.

5. The optical system of claim 1, wherein the beam splitter has a maximum thickness of less than 0.5 mm.

6. The optical system of claim 1, wherein the beam splitter has a plane-parallel geometry.

7. The optical system of claim 1, wherein the beam splitter is wedge-shaped.

8. The optical system of claim 1, wherein the beam splitter is wedge-section-shaped.

9. The optical system of claim 1, wherein the beam splitter is prism-shaped.

10. The optical system of claim 1, wherein the beam splitter comprises a material selected from the group consisting of magnesium fluoride (MgF₂), lithium fluoride (LiF), aluminum fluoride (AlF₃), calcium fluoride (CaF₂) and barium fluoride (BaF₂).

11. The optical system of claim 1, wherein the beam splitter consists of one material selected from the group consisting of magnesium fluoride (MgF₂), lithium fluoride (LiF), aluminum fluoride (AlF₃), calcium fluoride (CaF₂) and barium fluoride (BaF₂).

12. The optical system of claim 1, wherein the light entrance surface comprises an uncoated component.

13. The optical system of claim 1, wherein the light exit surface comprises an uncoated component.

14. The optical system of claim 1, wherein the operating wavelength is less than 150 nm.

15. The optical system of claim 1, wherein the operating wavelength is less than 120 nm.

16. The optical system of claim 1, wherein the operating wavelength is less than 30 nm.

17. The optical system of claim 1, wherein the operating wavelength is less than 15 nm.

18. The optical system of claim 1, wherein the optical system is a microscope.

19. The optical system of claim 1, wherein the optical system is a mask inspection system configured to inspect microlithography masks.

20. A method, comprising:
using the optical system of claim 1 to investigate a sample.
